(19) United States
(12) Patent Application Publication
(10) Pub. No.: US 2005/0258425 A1
(43) Pub. Date: Nov. 24, 2005

(54) Photoelectric conversion device, image scanning apparatus, and manufacturing method of the photoelectric conversion device

(76) Inventor: Yoshihiro Izumi, Kashihara-shi (JP)

Correspondence Address: NIXON & VANDERHYE, PC, 901 NORTH GLEBE ROAD, 11TH FLOOR, ARLINGTON, VA, 22203, US

(21) Appl. No.: 10/520,928

(22) PCT Filed: Jun. 25, 2003
(86) PCT No.: PCT/JP03/08057

§ 371 Date: Jan. 11, 2005

(30) Foreign Application Priority Data
Jul. 11, 2002 (JP) 2002-20286
Jun. 3, 2003 (JP) 2003-158501

(51) Int. Cl. H01L 29/04

(52) U.S. Cl. 257/72

(57) ABSTRACT

A conductive layer and a connection electrode of the image sensor are directly in contact with each other and are electrically connected to each other, so that a conventional conductive connector is unnecessary. The cost is reduced by omitting the conductive connector, and the cost is further reduced by reducing the processes. Since the conductive connector is unnecessary, accuracy is not required upon manufacturing, so that an image sensor of lower cost is provided. An opening portion is provided to form a new pixel capacitor between the conductive layer and a polar plate of the pixel capacitor section, so that the pixel capacitance is increased without largely changing the conventional processes.

### TECHNICAL FIELD

The present invention relates to a photoelectric conversion device, an image scanning apparatus, and a manufacturing method of the photoelectric conversion device whereby an electric signal according to intensity of incident light is outputted, more specifically to (a) a photoelectric conversion device which functions as an image sensor for scanning images such as a document and a photograph, (b) an image scanning apparatus having the same, and (c) a manufacturing method of the photoelectric conversion device.

### BACKGROUND ART

Recently, as an image scanning device for scanning a document or a photograph, there has been widespread use of a flat bed scanner which scans a two-dimensional image by causing a line sensor such as a CCD (Charge Coupled Device) line sensor having pixels disposed in a line manner (X-direction) to perform line scanning (Y-direction).

However, since a scanner having such line sensor is equipped with a bulky scanning mechanism for scanning a two-dimensional image, there is a limit in making the scanner thinner and lighter, and it is difficult to improve a scanning speed.

Then, in order to make the image scanning apparatus thinner and lighter and to improve the scanning speed, there is being developed an active matrix type two-dimensional image sensor (photoelectric conversion device) wherein photoelectric elements, such as a photodiode and a phototransistor, and switching elements, such as a thin film transistor, are disposed in a two-dimensional manner.

According to a structure using the two-dimensional image sensor, it is possible to scan the two-dimensional image without using the bulk scanning mechanism. Thus, compared with the flat bed scanner using a conventional CCD line sensor, it is possible to realize a thickness and a weight of the two-dimensional image sensor which are not more than 1/10 with respect to those of the flat bed scanner, and it is possible to realize a scanning speed 10 times as fast as that of the flat bed scanner, thereby realizing a user-friendly image scanning apparatus.

An example of such an image scanning apparatus is an image scanning apparatus (thin film photosensor) recited in Japanese Unexamined Utility Model Publication No. 8055/1990 (Jitsukaihei 2-8055)(Publication date: Jan. 18, 1990), and in Japanese Unexamined Patent Publication No. 243547/1993 (Tokukaihei 5-243547)(Publication date: Sep. 21, 1993).

The image scanning apparatus 31 is arranged so that each pixel of an active matrix array having pixels disposed in an XY-matrix manner has a switching TFT (Thin Film Transistor) 32, a photodetecting TFT 33 which functions as a photoelectric conversion element, and a pixel capacitor (storage capacitor) 34, as shown in FIG. 20.

In the photodetecting TFT 33 of each pixel, intensity of a detected light current Ip varies according to white/black (light/shade) of an object such as a document surface. The difference in the light current Ip of each pixel causes a difference in electric charge stored in the pixel capacitor 34 of each pixel. Electric charge distribution (in-plane distribution) of the pixel capacitor 34 is scanned by a switching TFT 32, a driving circuit 35 and a scanning circuit 36 sequentially, so that two-dimensional information of the object can be obtained. That is, the photodetecting TFT 33 functions as a photoelectric conversion element which outputs or varies an electric signal according to intensity of incident light. By using the image scanning apparatus 31 equipped with an image sensor having this photoelectric conversion element, it is possible to easily scan the two-dimensional image.

Here, a manufacturing process of the image sensor having the photoelectric conversion element such as the aforementioned phototransistor or photodiode is described.

First, the photoelectric conversion element constituted of a thin film phototransistor, for example, is formed on a substrate. Here, the photodiode or other photoelectric conversion element such as a photoconductor may be used as the photoelectric conversion element to be formed. The photoelectric conversion element is first formed on the substrate regardless of whether the image scanning apparatus is used as a one-dimensional line sensor or a two-dimensional area sensor.

Next, a protective layer having translucency is formed so as to cover the photoelectric conversion element that has formed on the substrate. The protective layer is formed to protect the photoelectric conversion element and to prevent deterioration of resolution that is caused by flaws and dusts brought about by a document etc. which would be in contact with the photoelectric conversion element.

Here, the protective layer is generally made of highly insulative material to protect the photoelectric conversion element. Thus, when the object such as a document contacts and is separated from the protective layer, a frictional force causes a static (frictional) electricity. Thus, the static electricity may cause such disadvantages that level shift of a scanning signal occurs in the photoelectric conversion element used to detect images, and that a signal processing section malfunctions.

In order to solve such problems, for example, Japanese Unexamined Patent Publication No. 71173/1989 (Tokukaihei 1-71173)(Publication date: Mar. 16, 1989) discloses an image scanning apparatus, having a one-dimensional line sensor structure, wherein a transparent conductive layer which functions as an antistatic (anti-electrostatic) layer whose potential is kept at a predetermined level is provided between the photoelectric conversion element and the protective layer provided thereabove. Thus, even if a static electricity occurs, it is possible to perform stable scanning. Further, a similar image scanning apparatus is disclosed in U.S. Pat. No. 4,982,079 (Publication date: Jan. 1, 1991), U.S. Pat. No. 5,086,218 (Publication date: Feb. 4, 1992), and U.S. Pat. No. 5,160,835 (Publication date: Nov. 3, 1992), that were filed claiming priority rights of an application recited in Japanese Unexamined Patent Publication No. 71173/1989 (Tokukaihei 1-71173).

Further, such antistatic layer is useful since it is possible to shield influence of external noises such as an inverter noise of an interior light for example.

Further, the foregoing structure brings about the following advantage. If each pixel has not only the photoelectric conversion element but also a pixel capacitor (storage capacitor), the antistatic layer increases the capacitance of the pixel, so that it is possible to keep the capacitance of the pixel capacitor (storage capacitor) large even if each pixel of the image sensor is packed highly and closely (densified).

While, Japanese Unexamined Patent Publication No. 245853/1992 (Tokukaihei 4-245853)(Publication date: Sep. 2, 1992) discloses a method for connecting a conductive layer (antistatic layer) to an electrode, having a one-dimensional line sensor structure, which is arranged differently from the structure recited in Tokukaihei 1-71173. For example, an image sensor (photoelectric conversion element) 41a of the image scanning apparatus is arranged so that a passivation layer 43, an impact relaxation layer 44, and an adhesive layer 45 are formed on and above a translucent insulating substrate 42 as shown in FIG. 21(a).

A microglass sheet (protective layer) 47 having a conductive layer 46 as an antistatic layer is combined therewith.

Here, an opening portion is partially formed in the passivation layer 43 and the impact relaxation layer 44. A ground electrode 48 is provided in the opening portion.

The conductive layer 46 is connected to the ground electrode 48, exposed at the opening portion, by using conductive resin (conductive connector) 49a.

Further, the image sensor is not limited to the foregoing structure. For example, the conductive layer 46 may be connected to the ground electrode 48 by using a stud bump (conductive connector) 49b so as to form an image sensor 41b (FIG. 21(b)), or the conductive layer 46 may be connected to the ground electrode 48 by having conductive particles (conductive connector) 49c contained in the adhesive layer 45 so as to form an image sensor 41c (FIG. 21(c)), or the conductive layer 46 may be connected to the ground electrode 48 by using microbeads 49d (conductive connector) which have been subjected to metal plating so as to form an image sensor 41d (FIG. 21(d)).

The image sensors 41a to 41d arranged in the foregoing manners are such that: the conductive layer 46 is connected to the ground electrode 48 by using the conductive resin 49a, the stud bump 49b, the conductive particles 49c contained in the adhesive layer 45, and the microbeads 49d that have been subjected to metal plating, respectively, as the conductive connector.

Thus, for example, a static electricity caused by friction between a document (not shown) and the microglass sheet 47 can be led from the conductive layer 46 positioned in lower surface of the microglass sheet 47, via each of the conductive connectors 49a-49d, to the ground electrode 48. In other words, it is possible to keep a potential of the conductive layer 46 at a predetermined level via the ground electrode 48 formed on the side of the translucent substrate 42. Thus, it is possible to perform stable scanning even if the static electricity occurs.

Further, in each of the image sensors 41a to 41d, a connection portion of the conductive layer 46 and the ground electrode 48 does not protrude toward a surface side (document side) of the image sensor having the microglass sheet 47, thereby realizing the image sensors 41a to 41d each of which has a flat surface.

However, according to the aforementioned method for connecting the conductive layer 46 to the electrode, a manufacturing cost is high and it is difficult to stably manufacture the image scanning apparatus. Further there is a possibility that the sufficient pixel capacitance cannot be obtained.

That is, each of the aforementioned image sensors 41a to 41d is arranged so that the ground electrode 48 and the conductive layer 46 are respectively formed on the translucent substrate 42 and the microglass sheet 47 that are formed differently from each other, and are then combined with each other.

Thus, the aforementioned conductive connectors 49a-49d are required in connecting the ground electrode 48 to the conductive layer 46.

Thus, this brings about such disadvantages that the manufacturing cost is increased since the conductive connectors 49a-49d are required, and that the process steps are increased, thereby further increasing the manufacturing cost.

Further, high accuracy is required in setting an added amount of the conductive connectors 49a-49d and in the step of combining the translucent substrate 42 with the microglass sheet 47, so as not to allow protrusion (protuberance) due to each conductive connector 49a-49d to spoil the flatness of the microglass sheet 47, so that it is difficult to stably manufacture the image scanning apparatus.

The present invention was conceived from the foregoing view point, and the first object thereof is to provide a photoelectric conversion device, an image scanning apparatus and manufacturing method of the photoelectric conversion device, in which the ground electrode 48 is connected to the conductive layer 46 without the aforementioned conductive connectors 49a-49d, and which can be realized by simple manufacturing process. In other words, the object of the present invention is to provide a photoelectric conversion device and an image scanning apparatus, and manufacturing method of the photoelectric conversion device, including a simple structure, which can be realized by simple processes so that the manufacturing cost can be reduced.

Further, the pixel of the image scanning apparatus is recently required to be more highly densified, so that it is necessary to increase the capacitance of the pixel capacitor (storage capacitor). Thus, there is a possibility that the structure recited in Tokukaihei 1-71173 and the structures of the image sensors 41a to 41d may not provide the sufficient pixel capacitance.

The present invention was conceived from the foregoing view point, and its second object is to provide a photoelectric conversion device, an image scanning apparatus, and a manufacturing method of the photoelectric device whereby it is possible to realize a new structure in which the pixel capacitance is increased without largely changing conventional processes. In other words, the object of the present invention is to provide a photoelectric conversion device, an image scanning apparatus, and a manufacturing method of the photoelectric device whereby it is possible to increase the pixel capacitance without largely changing conventional processes and it is possible to reduce the manufacturing cost.

### DISCLOSURE OF INVENTION

In order to solve the foregoing problems, a photoelectric conversion device according to the present invention includes: a first insulating layer, formed so as to cover a photoelectric conversion element and a connection electrode that are formed on a substrate, where the first insulating layer has an opening portion extending to the connection electrode; and a conductive layer formed on the first insulating layer, wherein the conductive layer is formed so as to be connected via the opening portion to the connection electrode.

Further, in order to solve the foregoing problems, a photoelectric conversion device according to the present invention includes: a first insulating layer formed so as to cover a photoelectric conversion element formed on a substrate; and a conductive layer formed on the first insulating layer, wherein the conductive layer is formed so as to be connected to a connection electrode, formed on the substrate, via an exposing portion provided on an end face of the first insulating layer in order to expose at least a part of the connection electrode.

Here, the photoelectric conversion element is a semiconductor element which outputs or varies an electric signal according to light intensity of incident light.

Thus, in the photoelectric conversion device arranged in the foregoing manner, the conductive layer is directly in contact with the connection electrode. The conductive layer may be in contact with the connection electrode via the opening portion provided in the first insulating layer, or via the exposing portion provided on the end face (peripheral side face, outside portion) of the first insulating layer. Thus, it is possible to connect the conductive layer to the connection electrode without using a conventional conductive connector.

Thus, it is possible to reduce the cost by omitting the conductive connector. Further, it is possible to further reduce the cost by omitting a process of making connection using the conductive connector.

Further, unlike the case of using the conductive connector, it is not necessary to adjust an added amount of the conductive connector, and high accuracy is not required upon combining step of the microglass sheet functioning as the second insulating layer, so that it is possible to easily manufacture the photoelectric conversion device.

Thus, it is possible to provide the photoelectric conversion device which can be manufactured at lower cost.

Note that, in the foregoing structure, if a plurality of photoelectric conversion elements are provided, and a pixel capacitor is provided corresponding to each photoelectric conversion element, and a combination of the photoelectric conversion element and the pixel capacitor is made to function as a pixel, it is possible to use the photoelectric conversion device as an image scanning sensor, for example.

Further, in the foregoing structure, the first insulating layer is provided on the photoelectric conversion element as a protective layer, so that it is possible to protect the photoelectric conversion element.

Further, the conductive layer is connected to the connection electrode, so that it is possible to lead (discharge) a static electricity, caused by friction between the photoelectric conversion device and a document etc., from the conductive layer via the connection electrode to the outside of the photoelectric conversion device. Thus, it is possible to avoid the level shift of a scanning signal in the photoelectric conversion element, and it is possible to prevent wrong operation (malfunctioning) in the signal processing section.

Further, it is also preferable to arrange the foregoing structure so that a potential of the conductive layer is kept at a desired level via the connection electrode. According to the arrangement, it is possible to control, in accordance with the desired potential, the static electricity caused by friction between the photoelectric conversion device and a document etc., thereby securely preventing the foregoing disadvantage.

Note that, the photoelectric conversion device may be expressed as follows. The photoelectric conversion device includes: a first insulating layer, formed so as to cover a photoelectric conversion element formed on a substrate, which is provided so that at least a part of a connection electrode formed on the substrate is exposed; and a conductive layer formed on the first insulating layer, wherein the conductive layer is connected via an (exposed) end face of the first insulating layer to the connection electrode.

In order to solve the foregoing problems, a photoelectric conversion device according to the present invention includes: a first insulating layer formed so as to cover a photoelectric conversion element formed on a substrate and a pixel capacitor section connected to the photoelectric conversion element; and a conductive layer formed on the first insulating layer, wherein a thickness of the first insulating layer is thinner in an area positioned on or above the pixel capacitor section than in other area.

Here, the photoelectric conversion element is a semiconductor element which outputs or varies an electric signal according to light intensity of incident light.

Further, the pixel capacitor (storage capacitor) section has polar plates opposite to each other, and can store electric charge in itself.

In the foregoing structure, if a plurality of photoelectric conversion elements are provided, and a pixel capacitor is connected to corresponding photoelectric conversion element, and a combination of the photoelectric conversion element and the pixel capacitor is made to act as a pixel, it is possible to use the photoelectric conversion device as an image scanning sensor for example.

According to the structure, a thickness of the first insulating layer is thinner in an area positioned on or above the pixel capacitor section (hereinbelow referred to as a contact area) than in other area (area other than the contact area). In other words, a thickness of the first insulating layer is thinner in an area, which is in contact with or above the pixel capacitor section, than in an area, which is not in contact with or above the pixel capacitor section.

Thus, when the thickness of the first insulating layer is appropriately adjusted to a desired thickness in the contact area, it is possible to form a new pixel capacitor, having a desired capacitance, between the pixel capacitor section and the conductive layer.

Here, any method may be used in appropriately adjusting the thickness of the first insulating layer in the contact area. The adjustment can be performed by a photolithograph technique or an etching technique.

Thus, it is possible to increase the pixel capacitance without largely changing conventional processes, and it is possible to obtain the sufficient pixel capacitance even when each pixel of the image sensor is packed highly and closely.

Further, since the extra cost is not so required, it is possible to reduce the manufacturing cost as a result when the same sufficient pixel capacitance is to be obtained.

Thus, it is possible to provide the photoelectric conversion device which can be manufactured at lower cost.

Note that, the photoelectric conversion device may be expressed as follows. The photoelectric conversion device includes: a first insulating layer formed so as to cover a photoelectric conversion element formed on a substrate and a pixel capacitor section connected to the photoelectric conversion element; and a conductive layer formed on the first insulating layer, wherein a thickness of the first insulating layer is thinner in an area, which is in contact with the pixel capacitor section, than in an area, which is not in contact with the pixel capacitor section.

Further, as long as the thickness of the first insulating layer is substantially thinner in the contact area than in an area other than the contact area, any arrangement may be possible. That is, for example, it is assumed that: when the thickness of the first insulating layer is not uniformed in the area other than the contact area, an area having a thickness thinner than the contact area is included in the area other than the contact area for any reason. At this time, an arrangement that a thickness of the contact area is thinner than an average thickness of whole the area other than the contact area may be possible.

In order to solve the foregoing problems, an image scanning apparatus according to the present invention includes any one of the aforementioned photoelectric conversion devices, wherein the photoelectric conversion device is used as an image scanning sensor.

Thus, since the photoelectric conversion device which can be manufactured at lower cost is used as an image sensor, it is possible to provide an image scanning apparatus which can be manufactured at lower cost.

Further, when the photoelectric conversion device is arranged so as to include the conductive layer connected to the aforementioned connection electrode, the static electricity does not cause a scanning error, so that it is possible to scan images without fail.

Further, when the photoelectric conversion device is arranged so as to include a new pixel capacitor between the pixel capacitor section and the conductive layer as described above, the pixel capacitance is increased, thereby improving the scanning quality.

In order to solve the foregoing problems, a method according to the present invention for manufacturing a photoelectric conversion device includes the steps of: forming a photoelectric conversion element and a connection electrode on a substrate; providing a first insulating layer for covering the photoelectric conversion element and the connection electrode, and forming an opening portion, extending to the connection electrode, in the first insulating layer; and forming a conductive layer, connected via the opening portion to the connection electrode, on the first insulating layer.

Further, in order to solve the foregoing problems, a method according to the present invention for manufacturing a photoelectric conversion device includes the steps of: forming a photoelectric conversion element and a connection electrode on a substrate; providing a first insulating layer for covering the photoelectric conversion element and the connection electrode, and forming an exposing portion on an end face of the first insulating layer so that at least a part of the connection electrode is exposed; and forming a conductive layer, connected via the exposing portion to the connection electrode, on the first insulating layer.

By using the manufacturing method of the photoelectric conversion device, it is possible to manufacture the aforementioned photoelectric conversion device. Thus, it is possible to omit the conductive connector, thereby reducing the manufacturing cost. Further, it is possible to omit the process for making connection using the conductive connector, thereby further reducing the cost.

Note that, the manufacturing method may be expressed as follows. The manufacturing method of the photoelectric conversion device includes the steps of: forming a photoelectric conversion element and a connection electrode on a substrate; forming a first insulating layer, covering the photoelectric conversion element and the connection electrode, which has an opening portion extending to the connection electrode; and forming a conductive layer, covering the first insulating layer, which is connected via the opening portion to the connection electrode.

Further, the manufacturing method may be expressed as follows. The manufacturing method of the photoelectric conversion device includes the steps of: forming a photoelectric conversion element and a connection electrode on a substrate; forming a first insulating layer, covering the photoelectric conversion element, which is formed so that at least a part of the connection electrode is exposed; and forming a conductive layer, covering the first insulating layer, which is connected via an end face of the first insulating layer to the connection electrode.

In order to solve the foregoing problems, a method according to the present invention for manufacturing a photoelectric conversion device includes the steps of: forming a photoelectric conversion element and a pixel capacitor section, connected to the photoelectric conversion element, on a substrate; forming a first insulating layer so as to cover the photoelectric conversion element and the pixel capacitor section; and forming a conductive layer on the first insulating layer; wherein the first insulating layer is formed so that a thickness of the first insulating layer is thinner in an area positioned on or above the pixel capacitor section than in other area.

By using the manufacturing method of the photoelectric conversion device, it is possible to manufacture the aforementioned photoelectric conversion device. Thus, it is possible to increase the pixel capacitance in the first insulating layer, which functions as the pixel capacitor, between the pixel capacitor section and the conductive layer without largely changing conventional processes.

Thus, it is possible to obtain the sufficient pixel capacitance even when each pixel of the image sensor is packed highly and closely.

Note that, any process may be used upon forming the first insulating layer. For example, it may be so arranged that: after uniformly providing the first insulating layer, a thickness of an area positioned on or above the pixel capacitor section is adjusted by a photolithograph technique or an etching technique.

For a fuller understanding of the nature and advantages of the invention, reference should be made to the ensuing detailed description taken in conjunction with the accompanying drawings.

### BRIEF DESCRIPTION OF DRAWINGS

FIG. 1(a) is a cross sectional view of one embodiment of a photoelectric conversion device according to the present invention in a manufacturing step, and FIG. 1(b) is a cross sectional view of the photoelectric device in another manufacturing step, and FIG. 1(c) is a cross sectional view of the photoelectric device in still another manufacturing step.

FIG. 2 is a schematic cross sectional view of one embodiment of an image scanning apparatus, according to the present invention, which has the photoelectric conversion device.

FIG. 3 is a circuit diagram showing an equivalent circuit which is a part of the image scanning apparatus.

FIG. 4 is a plan view showing a part of the photoelectric conversion device.

FIG. 5 is a cross sectional view schematically shows a part of a photoelectric conversion element of the photoelectric conversion device.

FIG. 6 is a flow chart for illustrating operations of the image scanning apparatus.

FIG. 7 is a cross sectional view showing a modification example of the photoelectric conversion device.

FIG. 8 is a cross sectional view showing another modification example of the photoelectric conversion device.

FIG. 9 is a cross sectional view showing a part of another embodiment of the photoelectric conversion device according to the present invention.

FIG. 10 is a circuit diagram showing an equivalent circuit of one pixel of the photoelectric conversion device.

FIG. 11 is a cross sectional view schematically showing a modification example of the photoelectric conversion device.

FIG. 12 is a cross sectional view schematically showing another modification example of the photoelectric conversion device.

FIG. 13 is a cross sectional view schematically showing still another modification example of the photoelectric conversion device.

FIG. 14 is a cross sectional view showing a part of still another embodiment of the photoelectric conversion device according to the present invention.

FIG. 15 is a circuit diagram showing an equivalent circuit which is a part of another embodiment of the image scanning apparatus according to the present invention, which has the photoelectric conversion device.

FIG. 16 is a plan view showing a part of the photoelectric conversion device.

FIG. 17 is a detail cross sectional view of a part of the photoelectric conversion device.

FIG. 18 is a cross sectional view showing a part of still another embodiment of the photoelectric conversion device according to the present invention.

FIG. 19 is a circuit diagram showing an equivalent circuit which is a part of still another embodiment of the image scanning apparatus, according to the present invention, which has the photoelectric conversion device.

FIG. 20 is a circuit diagram showing an equivalent circuit which is an example of a conventional image scanning apparatus.

FIG. 21(a) is a cross sectional view showing an example of the photoelectric conversion device in another example of the conventional image scanning apparatus, and FIG. 21 (b) is a cross sectional view showing another example of the photoelectric conversion device of the image scanning apparatus, and FIG. 21(c) is a cross sectional view showing still another example of the photoelectric conversion device of the image scanning apparatus, and FIG. 21(d) is a cross sectional view showing further another example of the photoelectric conversion device of the image scanning apparatus.

### BEST MODE FOR CARRYING OUT THE INVENTION

### Embodiment 1

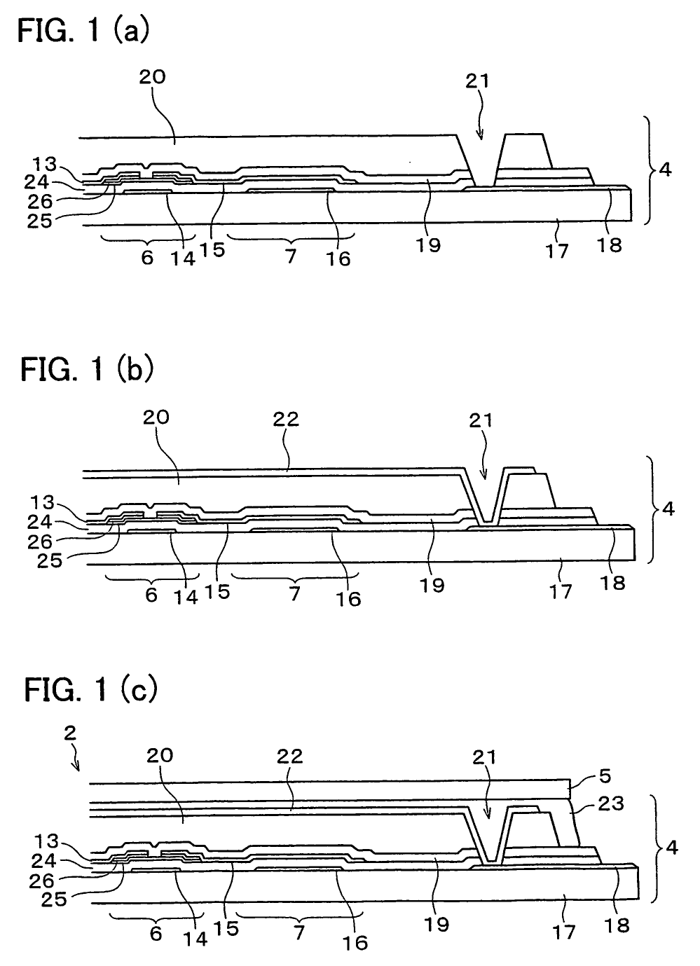

The following description will discuss one embodiment of the present invention referring to FIG. 1(a)-FIG. 1(c) to FIG. 8.

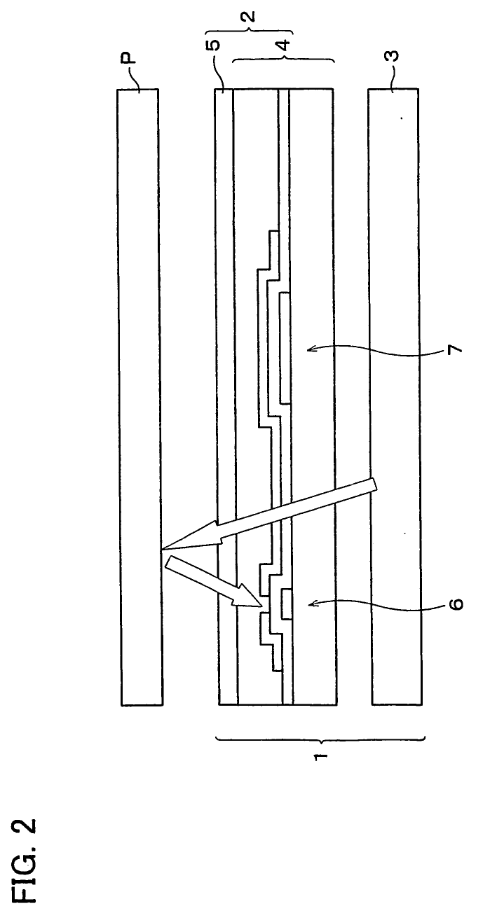

An image scanning apparatus 1 of the present embodiment includes an image sensor (photoelectric conversion device) 2 and a back light 3 as shown in FIG. 2.

The image sensor 2 includes a TFT (Thin Film Transistor) array 4 and a microglass sheet (second insulating layer) 5. The TFT array 4 has a TFT (Thin Film Transistor) section (photoelectric conversion element) 6 and a pixel capacitor (storage capacitor) section 7 as shown in FIG. 2.

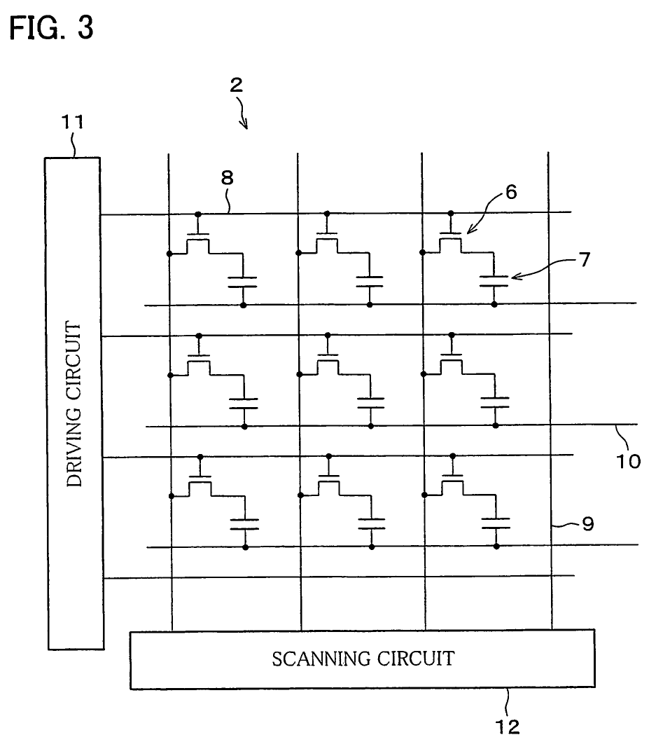

In more detail, as shown in FIG. 3, the TFT section 6 and the pixel capacitor section 7 are disposed on the TFT array 4 of the image sensor 2 in a two-dimensional XY matrix manner.

In FIG. 2, the image scanning apparatus 1 illuminate a document P by the back light 3, and the image sensor 2 detects the light reflected by the document P, so that the image scanning apparatus 1 scans an image of the document P. That is, the document P which is an object such as a photograph is brought into contact with a surface (on the side of the microglass sheet 5) of the image sensor 2 which functions as an active matrix substrate, thereby realizing a two-dimensional image scanning apparatus.

In more detail, light from the back light 3 passes through an opening (not shown) of the image sensor 2, so as to illuminate the document P as an object. The light that has reached the document P is reflected according to image information of the document P, and the reflected light reaches the TFT section 6, so that the reflected light is detected.

The image scanning apparatus 1 using such active matrix substrate does not require a bulk scanning mechanism for scanning a two-dimensional image, included in a scanner using a conventional line sensor for example. Thus, it is possible to realize a thinner and lighter image scanning apparatus, and it is possible to improve a scanning speed.

Note that, the back light 3 includes an LED (Light Emitting Diode) or a cold-cathode tube. Further, the microglass sheet 5 which functions as the second insulating layer is not necessarily in a substrate shape, but may be in a film shape.

A circuit structure of the image sensor 2 is described referring to FIG. 3.

In the image sensor 2, a gate wiring 8 connected to a driving circuit 11 and a source wiring 9 connected to a scanning circuit 12 are disposed in an XY matrix manner (lattice manner). The pixels are divided into each pixel unit by a lattice constituted of the respective wirings.

Note that, only a section including 3×3 pixels is shown in FIG. 3 for convenience, but it is needless to say that there may be provided a section including more pixels.

In each unit pixel, the TFT section 6 and the pixel capacitor section 7 are disposed. The TFT section 6 of the present embodiment acts as both (a) a phototransistor as a photosensor (photoelectric conversion element) and (b) a switching transistor for active driving.

Upon scanning the image, the driving circuit 11 and the scanning circuit 12 sequentially turn on the TFT section 6 as the switching transistor, so as to scan electric charge of the pixel capacitor section 7, thereby scanning each pixel.

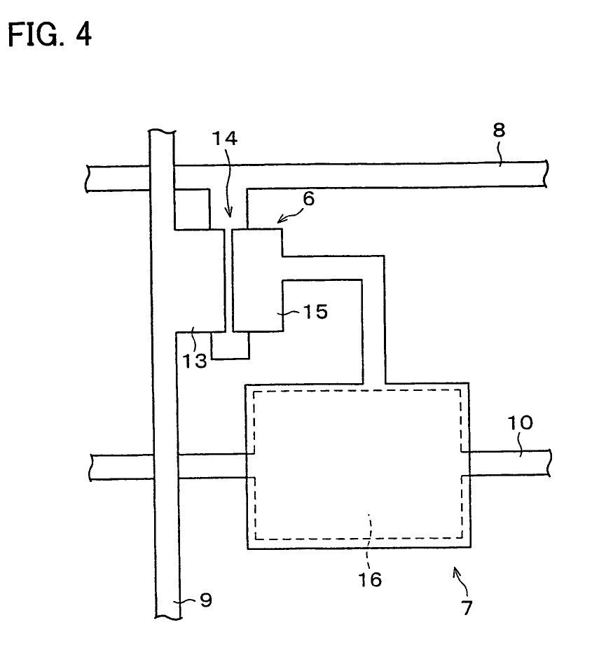

Further, as shown in FIG. 4, the TFT section 6 includes a source electrode 13, a gate electrode 14, and a drain electrode 15. The pixel capacitor section 7 includes a storage capacitor electrode 16.

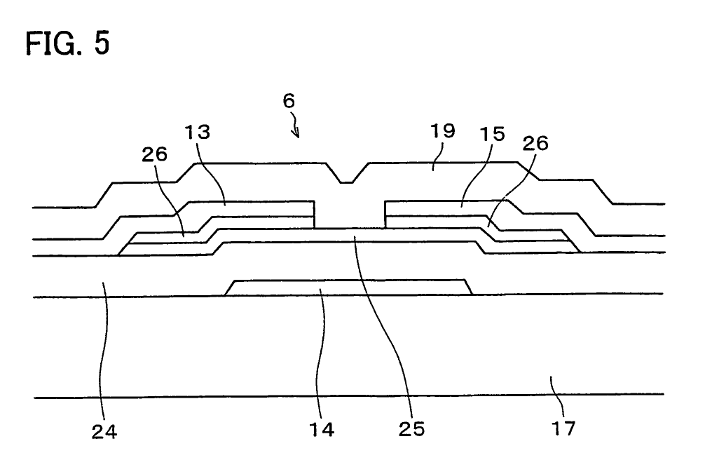

In more detail, as shown in FIG. 5, the TFT section 6 includes the gate electrode 14 on the substrate 17, a gate insulating film 24, a semiconductor layer 25, a contact layer 26, the source electrode 13, and the drain electrode 15. And an insulating protective film (first insulating layer, inorganic insulating film) 19 is provided thereon.

The gate electrode 14 is provided on the substrate 17 made of glass and the like.

The gate electrode 14 is constituted of a part of the gate wiring 8 or an electrode branched from the gate wiring 8, as shown in FIG. 4.

The gate electrode 14 behaves also as a light shielding film which stops direct incident light from a back surface of the TFT array 4 as the active matrix substrate to a channel of the TFT section 6. The gate electrode 14 contains a metal such as Al, Ta, Mo, Ti, and is a metallic film having an approximately 0.1 to 0.4 μm thickness.

On the gate electrode 14, the gate insulating film 24, made of SiNₓ, SiO₂, and the like, which has an approximately 0.3 to 0.5 μm thickness, is formed as shown in FIG. 5.

On the gate insulating film 24, the semiconductor layer 25, functioning as a channel, which has an approximately 0.05 to 0.2 μm thickness, is formed by using a-Si (amorphous Silicon), poly-Si and the like.

Further, on the semiconductor layer 25, the contact layer 26, made of a-Si of n+ and the like, which has an approximately 0.01 to 0.051 μm thickness, is formed. On the contact layer 26, the source electrode 13 and the drain electrode 15 are formed.

The source electrode 13 and the drain electrode 15 are metallic film using such as Al, Ta, Mo, Ti, and the like, or ITO (Indium Tin Oxide), and its thickness is approximately 0.1 to 0.31 μm.

While, as shown in FIG. 1(a), in the pixel capacitor section 7, the aforementioned gate insulating film 24 is used as a dielectric layer. The pixel capacitor section 7 includes the gate insulating film 24, provided between the storage capacitor electrode 16 formed in the same layer as the gate electrode 14 and an electrode extended from the drain electrode 15, as the dielectric layer. In the present embodiment, the pixel capacitor section 7 is formed in parallel with a forming process of the TFT section 6.

In this manner, the TFT section 6 is formed up to the source electrode 13 and the drain electrode 15 on the substrate 17, and the pixel capacitor section 7 is formed up to the electrode extended from the drain electrode 15. Thereafter, the insulating protective film 19 functioning as a passivation film is formed so as to cover the TFT section 6 and the pixel capacitor section 7.

The insulating protective film 19 is provided as a barrier film for protecting the TFT, which is a semiconductor element, from external moisture and impurity ion. As the insulating protective film 19, there is formed an SiNₓ film (0.2 to 0.5 μm thickness) having a minute film structure.

Further, on the insulating protective film 19, an organic insulating film (first insulating layer) 20 is formed.

Here, the organic insulating film 20 is provided to flatten a surface of the TFT array functioning as the active matrix substrate and to decrease a parasitic capacitance which is generated undesirably between a conductive layer 22 formed later and the TFT section 6 or a bus line.

The organic insulating film 20 can be formed by a coating device such as a spinner using a resin material, so that it is possible to easily flatten the surface. Further, a relative dielectric constant of the organic insulating film 20 is comparatively low, and is lower than a relative dielectric constant of the insulating protective film 19 functioning as the inorganic insulating film.

That is, it is easy to form the organic insulating film 20 so as to have an approximately 2 to 5 μm thickness, which is thicker than a 0.5 μm thickness generally used in the insulating protective film 19 as the inorganic insulating film. Thus, the insulating protective film 19 whose relative dielectric constant is high is made thinner, and the organic insulating film 20 is made thicker, so that it becomes easy to decrease the parasitic capacitance which is generated between the conductive layer 22 and the TFT section 6 or the bus line as described later.

While, in the image sensor 2 which functions as the photoelectric conversion device of the present embodiment, a connection electrode 18 is formed in a predetermined position of a peripheral portion of the substrate 17 as shown in FIG. 1(a).

The position in which the connection electrode 18 is formed is not particularly limited, but it is preferable to form the connection electrode 18 in a periphery (for example, four corners) of an active area where wirings are disposed in a lattice manner.

As shown in FIG. 1(a), the connection electrode 18 is made of the same material, in the same process, in the same layer, as the gate electrode 14 of the TFT section 6. The connection electrode 18 may be formed in the same layer as the source electrode 13 of the TFT section 6.

Further, as in the TFT section 6 and the pixel capacitor section 7, the gate insulating film 24, the insulating protective film 19, and the organic insulating film 20 are formed on the connection electrode 18.

Further, as shown in FIG. 1(a), in an area where the connection electrode 18 is formed, an opening portion 21 is provided on the gate insulating film 24, the insulating protective film 19, and the organic insulating film 20, which are positioned on or above the connection electrode 18. The connection electrode 18 positioned in a lower layer is exposed in a bottom of the opening portion 21.

Here, since the gate insulating film 24 and the insulating protective film 19 are made of an SiNₓ film, it is possible to easily form the opening portion 21 as a contact hole by using a known photolithography technique and a known etching technique.

Further, when the organic insulating film 20 is formed by using resin, such as acrylic resin, having photosensitivity, it is possible to form the opening portion 21 by the known lithography technique. In this manner, it is possible to realize the TFT array 4, included in the image sensor 2, under a condition shown in FIG. 1(a).

Next, as shown in FIG. 1(b), in the TFT array 4 under the condition shown in FIG. 1(a), a conductive layer 22 which functions as an antistatic (anti-electrostatic) layer is formed on a substantially entire surface of the TFT array 4, including the organic insulating film 20, so as to cover the TFT section 6, the pixel capacitor section 7, and the bus line. The conductive layer 22 includes a translucent conductive film such as an ITO, and has a 0.1 to 0.3 μm thickness.

Thus, the conductive layer 22 included in the image sensor 2 is formed so as to be connected via the opening portion 21 to the connection electrode 18. The conductive layer 22 is formed so as to cover, respectively and continuously, an upper surface of the organic insulating film 20, a side surface of the organic insulating film 20 in the opening portion 21, and a surface of the connection electrode 18 exposed in the opening portion 21.

Thus, the conductive layer 22 has electric connection with the connection electrode 18 disposed under the organic insulating film 20. Note that, an end portion (not shown) of the connection electrode 18 is connected to an external ground potential for example.

Further, as shown in FIG. 1(c), on the conductive layer 22, the microglass sheet 5 which functions as the second insulating layer is combined by using adhesive 23. The microglass sheet 5 is a thin glass sheet having an approximately 501 μm thickness. The adhesive 23 used to combine the microglass sheet 5 on the conductive layer 22 is transparent adhesive such as acrylic resin or epoxy resin. In this manner, the TFT array is formed, thereby manufacturing the image sensor 2.

The image scanning apparatus 1 having the image sensor arranged in the foregoing manner uses the image sensor 2 as an image scanning sensor, and scans the image of the document P by the following steps.

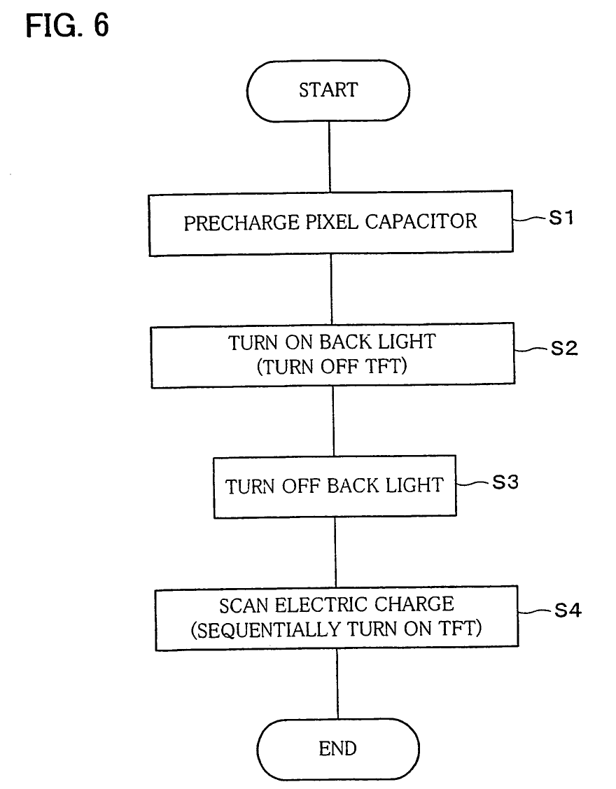

As shown in FIG. 6, in S1, the pixel capacitance of the pixel capacitor section 7 is precharged by using the source wiring 9 or a capacitor wiring 10. Here, when the pixel capacitance is precharged by using the source wiring 9, it is necessary to turn on the TFT section 6.

Next, in S2, turn on the back light 3 and the back light 3 illuminate the image sensor 2 for a predetermined period with the TFT section 6 kept off state. Thus, for example, the light reflected by the document P brightens the image sensor 2 for a predetermined period. In this step, in an area which receives intense reflected light, the light current Ip flowing between the source electrode 13 and the drain electrode 15 increases, so that the electric charge of the pixel capacitor section 7 that has been precharged is discharged.

While, the electric charge of the pixel capacitor section 7 is maintained in an area which does not receive the reflected light, for example.

As described above, in S2, the TFT of the TFT section 6 is used as a photodetecting (photosensor) TFT (photoelectric conversion element).

Next, in S3, turn off the back light 3 to light up. And then, in S4, the TFT of the TFT section 6 is turned on sequentially by using the driving circuit 11 and the scanning circuit 12. Thus, the electric charge remaining in the pixel capacitor section 7 is detected sequentially, thereby scanning a plane distribution of the image information.

As described above, in S4, the TFT of the TFT section 6 is used as a switching TFT.

As described above, the image sensor 2 according to the present embodiment is arranged so that the conductive layer 22 is directly in contact with the connection electrode 18.

Here, in the image sensor 2, the conductive layer 22 corresponds to the antistatic layer of the background art, and the connection electrode 18 corresponds to the ground electrode of the background art.

According to the arrangement, it is possible to provide the image scanning apparatus without the conductive connectors 49a-49d of the background art. Thus, it is possible to reduce the cost by omitting the conductive connectors 49a-49d, and it is possible to further reduce the cost by omitting the process of using the conductive connectors 49a-49d.

Further, since the conductive connectors 49a-49d are not used, it may not arise that the flatness of the microglass sheet 5 is spoiled by the influence upon bonding by the conductive connectors 49a-49d. Thus, it is possible to realize stable manufacture, thereby providing the image sensor 2 which can be easily manufactured at lower cost.

Further, it is possible to discharge the static electricity, caused by friction against the document P, to the connection electrode 18 via the conductive layer 22 which is electrically connected to the connection electrode 18, even when the conductive connectors 49a-49b are not used. Thus, it is possible to stably perform the scanning with a potential of the conductive layer 22 kept at a predetermined level.

Further, since the image scanning apparatus 1 of the present embodiment has the aforementioned image sensor 2, it is possible to reduce the cost and to stably perform the scanning.

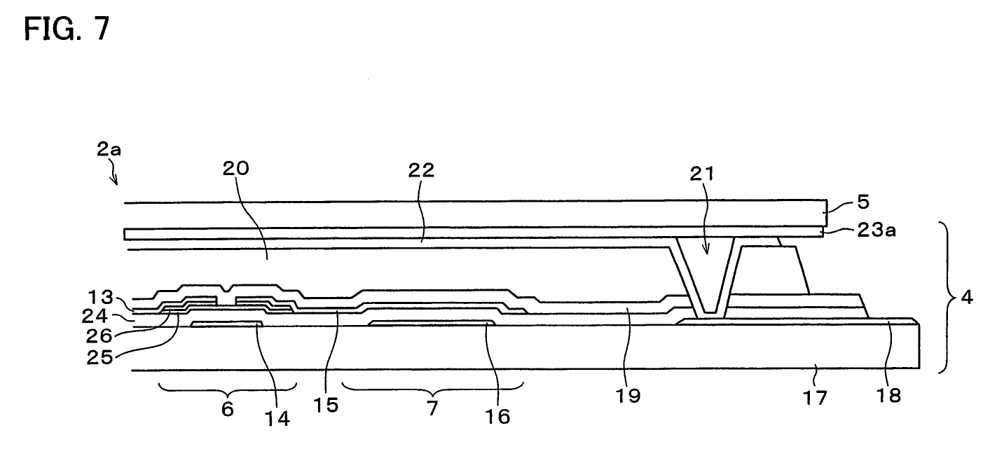

Note that, the structure of the present invention is not limited to the structure described in the aforementioned embodiment. Thermoplastic adhesive sheet 23a made of PVA and the like may be used instead of the transparent adhesive 23 of FIG. 1(c) so as to form an image sensor 2a as shown in FIG. 7.

In this case, unlike the ordinary adhesive 23, it is not necessary to apply the adhesive 23 to the bonding surface. Thus, the adhesive sheet 23a of a predetermined size is inserted into a gap between the conductive layer 22 and the microglass sheet 5 of the image sensor 2, and a heating process is performed. Thus, the manufacturing steps are further simplified, thereby reducing the manufacturing cost for example.

Further, the present invention may be arranged so that a coating-type insulating film is used instead of the microglass sheet 5, which functions as the second insulating layer positioned in an outermost surface, so as to form an image sensor 2b.

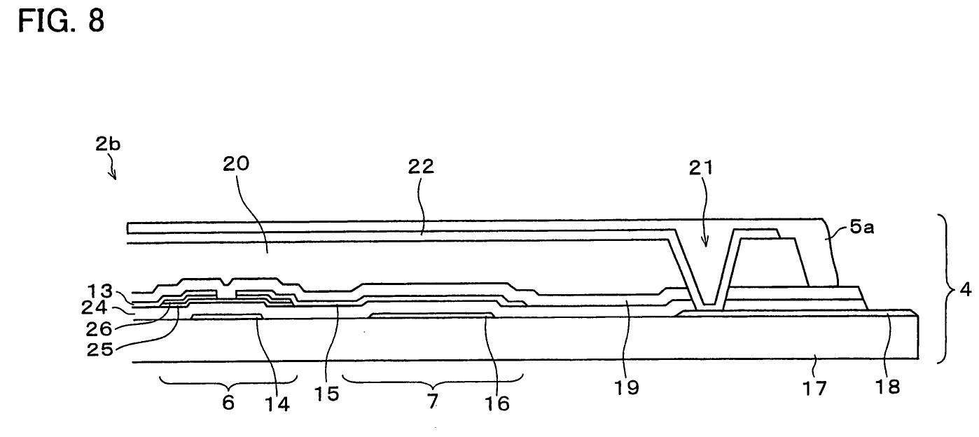

That is, as shown in FIG. 8, it may be so arranged that: for example, liquid coating agent such as coating glass made mainly of alkoxysilane is coated to a surface of the conductive layer 22, and is then dried, so as to form a glass film 5a which functions as the second insulating layer. In this arrangement, it is possible to omit the adhesive 23.

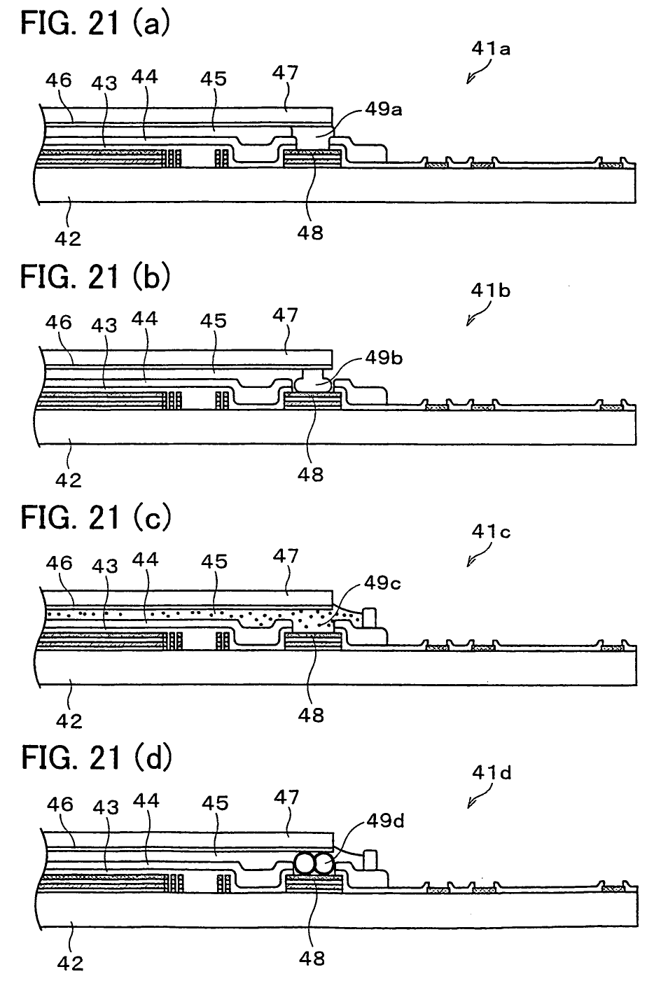

Here, in the conventional structures shown in FIG. 21(a) to FIG. 21(d), the conductive layer 46 is formed on one side of the microglass sheet 47, and is then combined with one side of the translucent insulating substrate 42, so that it is difficult to use such coating-type insulating film on the outermost surface.

While, in the present invention, it is possible to provide the conductive layer 22 on the side of the substrate 17 of the image sensor 2, so that it is possible to easily use a glass film 5a as the coating-type insulating film.

Further, the aforementioned embodiment describes the arrangement in which the conductive layer 22 is connected to the connection electrode 18 via the opening portion 21 of the organic insulating film 20 which functions as the first insulating layer as shown in FIG. 1(c), but the present invention is not limited to this.

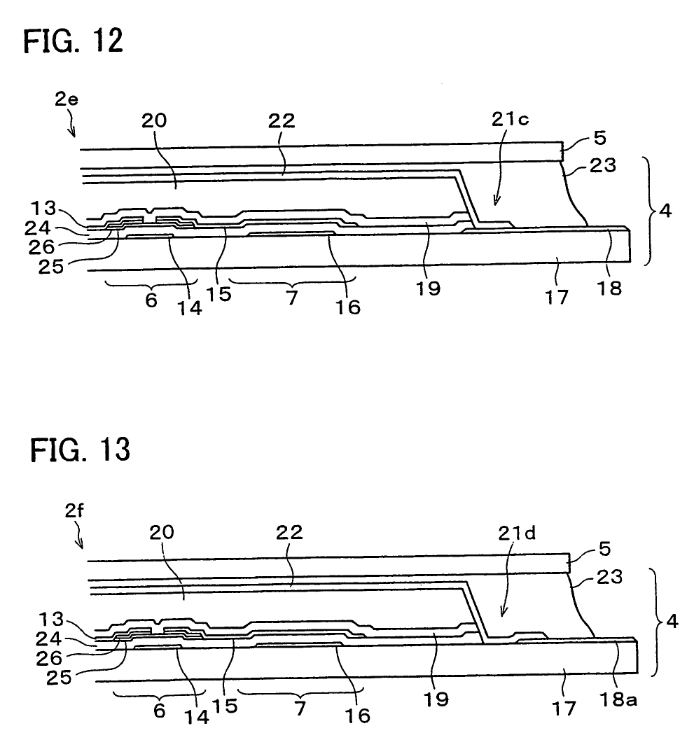

Like an image sensor 2e shown in FIG. 12 for example, the conductive layer 22 may be connected to the connection electrode 18 via an exposing portion 21c provided on an end face (peripheral side face) of the organic insulating layer 20.

That is, as shown in FIG. 12, the TFT section 6 which functions as the photoelectric conversion element and the connection electrode 18 are formed on the substrate 17, and there are provided the insulating protective film 19 and the organic insulating layer 20 which function as the first insulating layer covering the TFT section 6 and the connection electrode 18. Here, the connection electrode 18 is formed in a predetermined area positioned in the periphery of the substrate 17. Further, the exposing portion 21c is provided on the end face (end section) of the insulating protective film 19 and the organic insulating layer 20 so that at least a part of the connection electrode 18 is exposed. Thereafter, the conductive layer 22 is formed to cover the insulating protective film 19 and the organic insulating layer 20, and to connect to the connection electrode 18 via the exposing portion 21c.

Alternately, like an image sensor 2f shown in FIG. 13 for example, the conductive layer 22 may be connected to the connection electrode 18a via the exposing portion 21d. That is, a position where the connection electrode 18a is provided may be differed from a position of the connection electrode 18, in consideration of a position where the exposing portion 21d is provided. Further, aforementioned arrangement may be expressed as: the exposing portion 21d is provided so that the insulating protective film 19 and the organic insulating layer 20 are apart from the connection electrode 18a.

The arrangements of FIG. 12 and FIG. 13 described above enable the conductive layer 22 to be in contact with the connection electrodes 18 or 18a via the exposing portions 21c or 21d, so that it is possible to obtain the same effects as the aforementioned embodiment.

### Embodiment 2

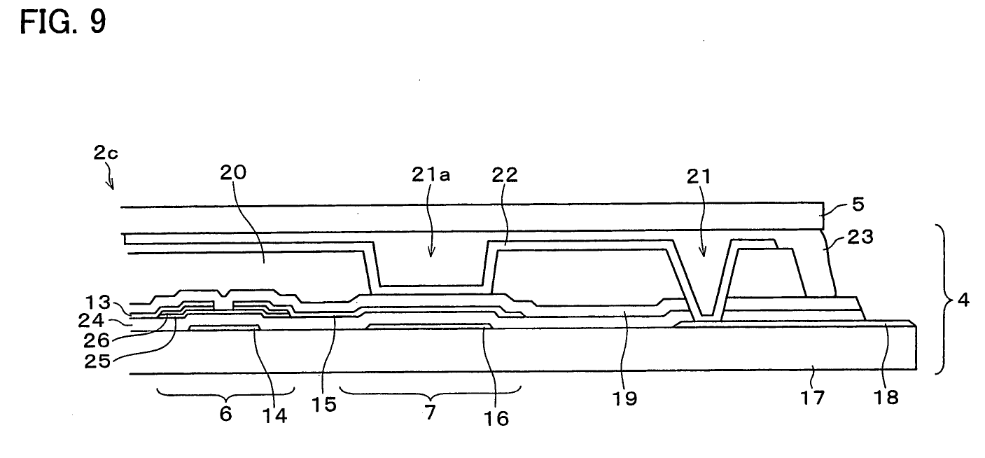

The following description will discuss another embodiment of the present invention referring to FIG. 9 to FIG. 11. Note that, the same reference signs are given to members having the same functions as the members of the aforementioned embodiment, and description thereof is omitted. Further, various kinds of characteristics described in Embodiment 1 can be applied, in combination, to the present embodiment.

As shown in FIG. 9, an image sensor (photoelectric conversion device) 2c of the present embodiment is different from the aforementioned image sensor 2 in that not only the opening portion 21 for exposing the connection electrode 18 is provided, but also an opening portion 21a is formed to be positioned above the pixel capacitor section 7.

The opening portions 21 and 21a are formed as follows.

As in the aforementioned embodiment, the gate electrode 14, the gate insulating film 24, the semiconductor layer 25, the contact layer 26, the source electrode 13, and the drain electrode 15 are respectively formed in the TFT section 6 positioned on the substrate 17. Further, the pixel capacitor electrode 16, the gate insulating film 24, and an electrode extended from the drain electrode 15 are respectively formed in the pixel capacitor section 7. Further, the gate insulating film 24 is formed on the connection electrode 18 positioned on the substrate 17.

Under this condition, the insulating protective film 19 and the organic insulating film 20 are formed so as to cover the TFT section 6, the pixel capacitor section 7, and the connection electrode 18.

Thereafter, as in the aforementioned embodiment, the opening portion 21 for exposing the connection electrode 18 is formed. Further, the opening portion 21a is formed in the organic insulating film 20 functioning as the first insulating layer in an area above (or on) the pixel capacitor section 7.

After forming the opening portions 21 and 21a in the foregoing manner, the conductive layer 22 is formed.

The conductive layer 22 is formed continuously to cover not only an upper surface of the organic insulating film 20, a side surface of the organic insulating film 20 in the opening portion 21, and a surface of the connection electrode 18 exposed in the opening portion 21, but also a surface of the opening portion 21a. Further, on the conductive layer 22, the microglass sheet 5 which functions as the second insulating layer is combined by using the adhesive 23.

In the image sensor 2c formed in the foregoing manner, the insulating protective film 19 is sandwiched by an extended portion of the drain electrode 15 of the TFT section 6 and the conductive layer 22. Here, the extended portion of the drain electrode 15 is formed by extending the drain electrode 15, which is positioned opposite to the storage capacitor 16, in the structure of the pixel shown in FIG. 4 for example. Thus, a second pixel capacitor in which the insulating protective film 19 functions as the storage capacitor is formed.

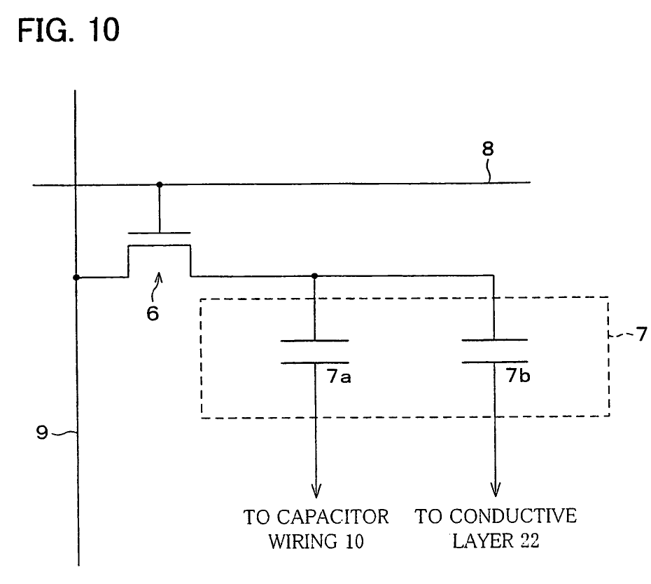

That is, as schematically shown by an equivalent circuit diagram of FIG. 10, besides the first pixel capacitor 7a constituted of the storage capacitor electrode 16 and the extended portion of the drain electrode 15, the second pixel capacitor 7b is newly connected thereto in parallel.

In this manner, the first pixel capacitor 7a, originally formed in the pixel, in which the gate insulating film 24 functions as the dielectric layer, and the second pixel capacitor 7b, formed as an advantage of the present embodiment, in which the insulating protective film 19 functions as the dielectric layer, are disposed in parallel. Thus, it is possible to increase a total pixel capacitance of the pixel capacitor section 7.

Note that, the capacitance of the second pixel capacitor 7b can be adjusted as follows: a width and a depth of the opening portion 21a are adjusted upon forming the opening portion 21a so as to realize a desired thickness and a desired area of the first insulating layer, constituted of the organic insulating film 20 and the insulating protective film 19, which is sandwiched between the conductive layer 22 and the extended portion of the drain electrode 15. In the present embodiment, particularly, the thickness of the first insulating layer constituted of the organic insulating film 20 and the insulating protective film 19 is thinner in an area sandwiched between the conductive layer 22 and the extended portion of the drain electrode 15 than in other area.

As a result, it is possible to increase the pixel capacitance without increasing the number of special processes. Thus, it is possible to obtain the sufficient pixel capacitance even when each pixel of the image sensor is packed highly and closely. Therefore, it is possible to perform the scanning without fail according to the image scanning apparatus having the image sensor 2c.

Here, generally, it is necessary to increase an area of a polar plate for the capacitance or to make the dielectric layer thinner so as to increase a value of the capacitance such as the pixel capacitance. Under such condition that the pixel is highly densified in recent years, it is difficult to increase the area of the polar plate.

Then, if the thickness of the gate insulating film 24 functioning as the dielectric layer is merely made thinner so as to increase the capacitance of the first pixel capacitor 7a, a property of the TFT of the TFT section 6 changes since the gate insulating film 24 is formed in the same layer as the gate insulating film 24 of the TFT section 6.

On the other hand, if the second pixel capacitor 7b is formed as described above, even when the thickness of the insulating protective film 19 is changed, the property of the TFT of the TFT section 6 is not greatly influenced. Thus, compared with the structure in which only the first pixel capacitor 7a is provided, it is possible to easily increase the capacitance value of the pixel capacitor section 7.

Further, the image sensor 2c is arranged so that the organic insulating film 20 remains in an area other than an area above the pixel capacitor section 7. Thus, this structure does not cause the increase in the parasitic capacitance in the area, such as a disposing area of the bus line, other than the area above the pixel capacitor section 7.

Thus, upon forming the insulating protective film 19, it is particularly preferable to use a material whose relative dielectric constant is higher than that of the organic insulating film 20. According to the arrangement, it is possible to minimize the increase in the parasitic capacitance of the area other than the area above the pixel capacitor section 7 while increasing the capacitance of the second pixel capacitor. Specifically, an SiNₓ film whose relative dielectric constant is approximately 7 is used as the insulating protective film 19, and acrylic resin whose relative dielectric constant is approximately 3.5 is used as the organic insulating film 20.

As described above, the image sensor 2c of the present embodiment is arranged so that: the opening portion 21a is formed also on or above the pixel capacitor section 7, and the pixel capacitor in which the insulating protective film 19 functions as the storage capacitor is provided between the conductive layer 22 and the extended portion of the drain electrode 15.

Thus, it is possible to increase the pixel capacitance without largely changing the conventional processes, and it is possible to obtain the sufficient pixel capacitance upon highly densifying the pixel of the image sensor.

Further, in the image scanning apparatus having the image sensor 2c, it is possible to perform the scanning without fail.

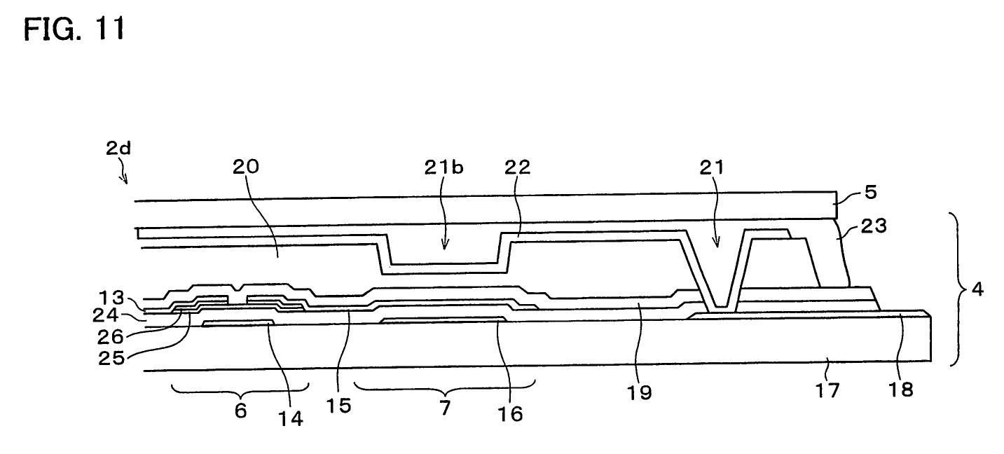

Note that, the present invention is not limited to the arrangement of the image sensor 2c in which the opening portion 21a is provided on a whole organic insulating film 20 positioned on upper portion of the pixel capacitor section 7. As shown in FIG. 11, the present invention may be arranged so that there is provided the opening portion (opening section) 21b by which the thickness of the organic insulating film 20 is made thinner above the pixel capacitor section 7 than in other area so as to increase the pixel capacitance, thereby forming an image sensor 2d.

Further, the aforementioned embodiment describes the arrangement in which the conductive layer 22 is directly connected to the connection electrode 18 as shown in FIG. 9, but the present invention is not limited to this. Even if it may be so arranged that the conductive layer 22 is not directly connected to the connection electrode 18 for example, there is no problem as long as a new pixel capacitor is formed between the conductive layer 22 and the polar plate of the pixel capacitor section 7 with the opening portion 21a formed.

As described above, the aforementioned embodiment describes the arrangement in which there is provided the TFT section 6 having a bottom gate type TFT structure as the image sensors 2, 2a, 2b, 2c, and 2d, but the present invention is not limited to this. It may be so arranged that there is provided a TFT section having a top gate type TFT structure.

Further, the aforementioned embodiment describes an example where the image sensors 2, 2a, 2b, 2c, and 2d each of which functions as the photoelectric conversion device is applied to the two-dimensional active matrix array, but the present invention is not limited to this. This structure can be applied to a one-dimensional sensor array or a single photodetecting element.

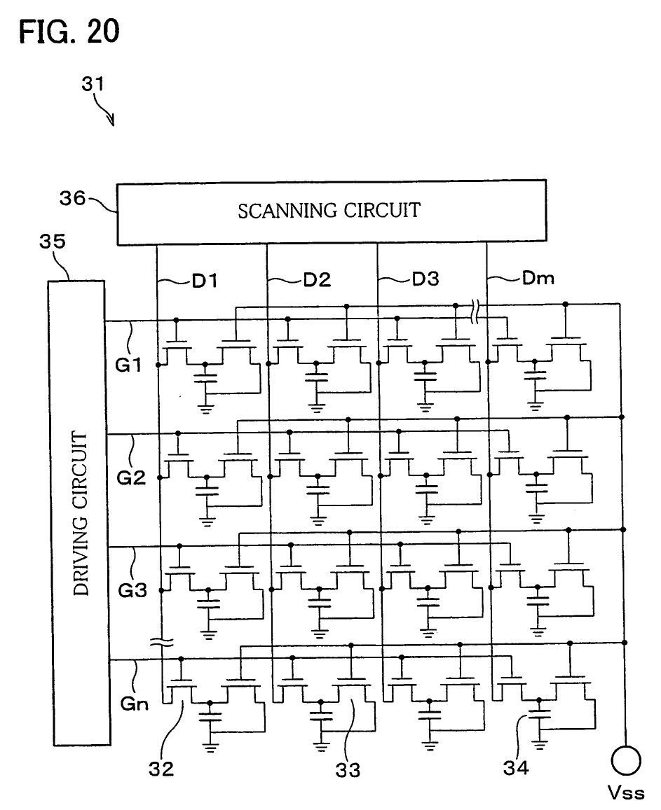

Further, the aforementioned embodiment describes the arrangement: in which a single TFT of the TFT section 6 is disposed in each unit pixel as the image sensors 2, 2a, 2b, 2c, and 2d for example, so as to function as both a switching TFT and a photodetecting TFT, but the present invention is not limited to this. For example, it may be so arranged that a switching TFT 32 and a photodetecting TFT 33 are provided in each unit pixel as shown in FIG. 20.

Further, as the photoelectric conversion element used in the photoelectric conversion device, not only the thin film transistor structure but also a photoconductor element and a photodiode element can realize the features of the present invention.

### Embodiment 3

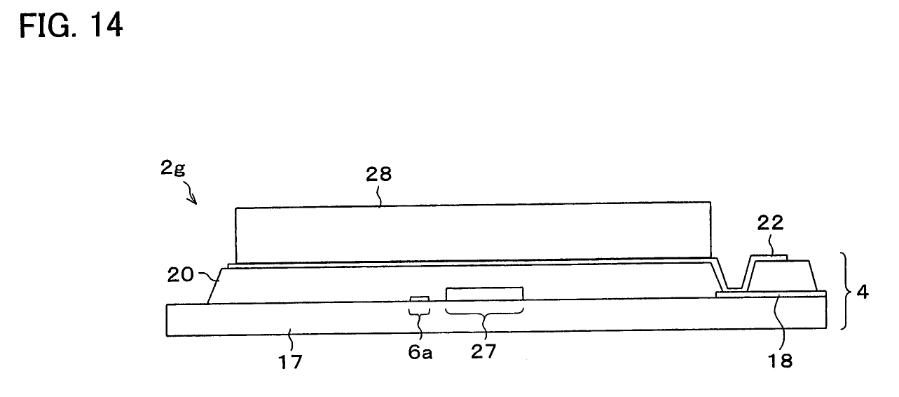

The following description will discuss still another embodiment of the present invention referring to FIG. 14 to FIG. 17. Note that, the same reference signs are given to members having the same functions as the members of the aforementioned embodiments, and description thereof is omitted. Further, various kinds of characteristics described in Embodiment 1 can be applied to the present embodiment.

An image sensor (photoelectric conversion device) 2g of the present embodiment is a device such that the photoelectric conversion device according to the present invention is applied to an X ray detector.

The image sensor 2g includes a TFT section 6a which functions as a switching transistor for active driving and a photodiode 27 which functions as a photosensor (photoelectric conversion element) that are provided on the substrate 17 as shown in FIG. 14. In this manner, the image sensor 2g is different from the image sensor 2 of Embodiment 1 in that the photodiode 27 is provided instead of the pixel capacitor section 7. As the photodiode 27, it is possible to preferably use a photodiode having a PIN junction (or MIS junction) of Si for example.

Further, as shown in FIG. 14, the image sensor 2g has a conversion layer 28 for converting a radiant ray into light.

Here, the conversion layer 28 has a function for converting a radiant ray (radiant rays) into light. The radiant ray is an X ray for example, but is not limited to this. The radiant ray may be an ultraviolet ray. In more detail, the conversion layer 28 has a function for converting an X ray which is an electromagnetic wave whose wave length ranges from 0.01 to dozens nm, or an ultraviolet ray which is an electromagnetic wave whose wave length ranges from dozens to 360 nm, into visible light (whose wave length ranges approximately from 360 to 830 nm).

More specifically, the conversion layer 28 is made of light-emitting material which emits light upon receiving the radiant ray for example. Examples of the light-emitting material include: CsI used in a scintillator; and a sense-amplifying sheet used in an X-ray film. Examples of the light-emitting material are not limited to them. As an inorganic material used in a scintillator for example, a crystal of Nal doped with a small amount of thallium or a crystal of an oxidized material such as BGO may be used.

As shown in FIG. 14, the conversion layer 28 may be formed directly on the conductive layer 22. Alternately, it may be so arranged that, for example, a transparent insulating film (second insulating layer) such as the microglass sheet 5, resin film, or coating glass is provided on the conductive layer 22, and the conversion layer 28 is formed thereon.

In more detail, as the conversion layer 28, CsI (strictly, CsI:Na doped with Na) may be provided by vacuum deposition for example. The CsI made by the vacuum deposition becomes a needle-shaped (spicula) crystal (referred to also as an optic fiber structure), and this forms a film constituted of a batch of needle-shaped crystals each of which has a diameter ranging from 5 to 10 μm and a length ranging from 200 to 500 μm.

Further, it may be so arranged that: for example, particles of a fluorescent material (Gd₂O₂S:Tb and the like) are dispersed on a binder so as to be printed on the conductive layer 22 or on the second insulating layer, thereby forming the conversion layer. Further, it may be so arranged that: a sense-amplifying sheet in which particles of a fluorescent material (Gd₂O₂S:Tb and the like) are applied to a base material such as an insulating sheet is disposed on the conductive layer 22 or the second insulating layer.

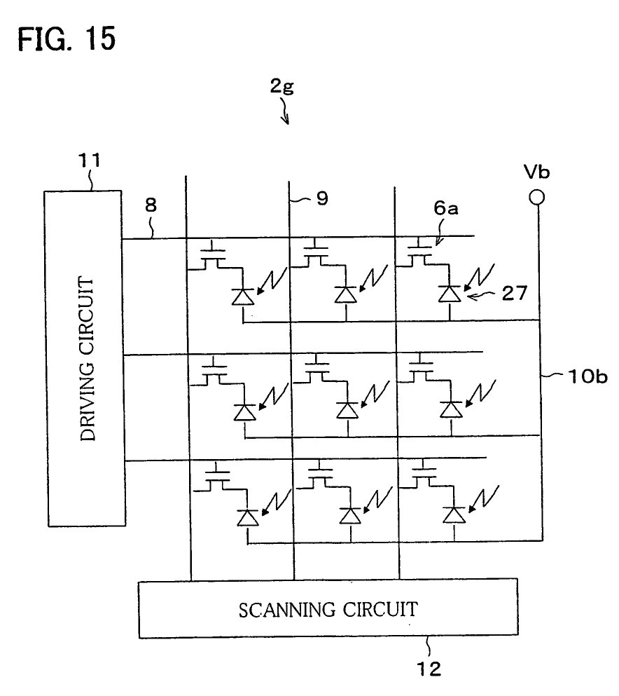

Note that, FIG. 14 shows only a pair of the TFT section 6a and the photodiode 27 for convenience, but the arrangement is not limited to this. On the substrate 17, also other pairs of the TFT section 6a and the photodiode 27 (both of which are not shown) are provided. That is, as shown in FIG. 15, the image sensor 2 is arranged in an array manner so that the TFT section 6a and the photodiode 27 are disposed in a two-dimensional XY matrix manner. Note that, FIG. 15 shows only a section having 3×3 pixels for convenience, but it is needless to say that the section may have more pixels.

In the image sensor 2g, the gate wiring 8 connected to the driving circuit 11 and the source wiring 9 connected to the scanning circuit 12 are disposed in an XY matrix manner (lattice manner). A lattice constituted of the respective wirings partitions the image sensor 2g into each pixel unit as the pixel constituted of the TFT section 6a and the photodiode 27. In this manner, the image sensor 2g may be arranged so that the TFT element and the photoelectric conversion element are individually formed in each pixel. Further, the photodiode 27 is connected to a bias power source Vb via a bias wiring 10b.

Upon scanning the image, the driving circuit 11 and the scanning circuit 12 sequentially turn on the TFT section 6a functioning as the switching transistor and scan electric charge (or voltage) stored in the photodiode 27 as described later, thereby scanning each pixel.

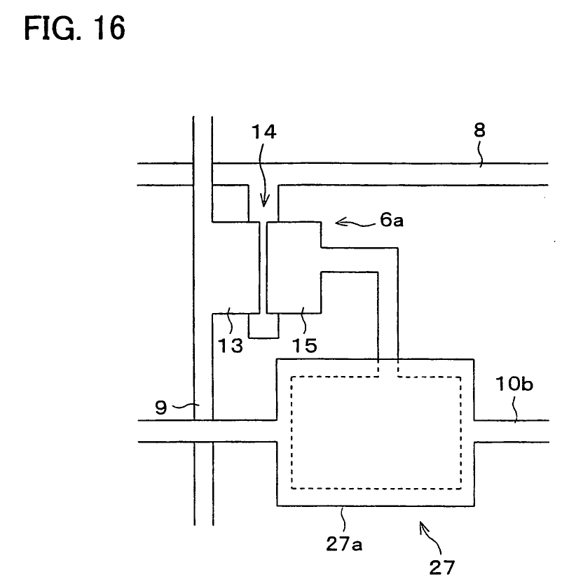

Further, the TFT section 6a includes the source electrode 13, the gate electrode 14, and the drain electrode 15, as shown in FIG. 16. The photodiode 27 includes a bias electrode (transparent electrode) 27a connected to the bias wiring 10b.

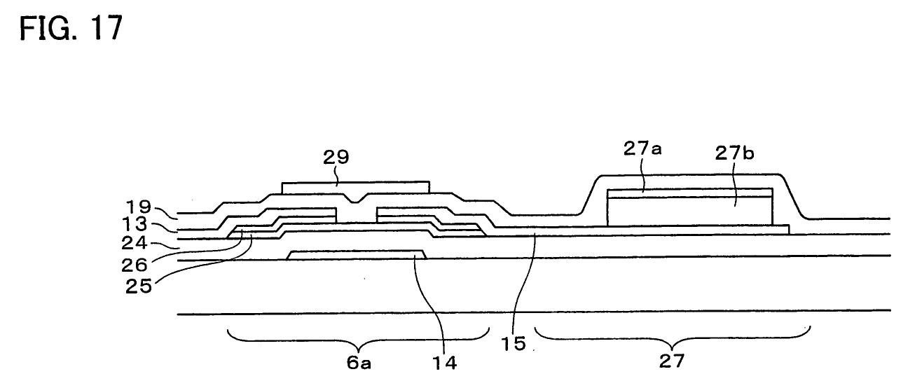

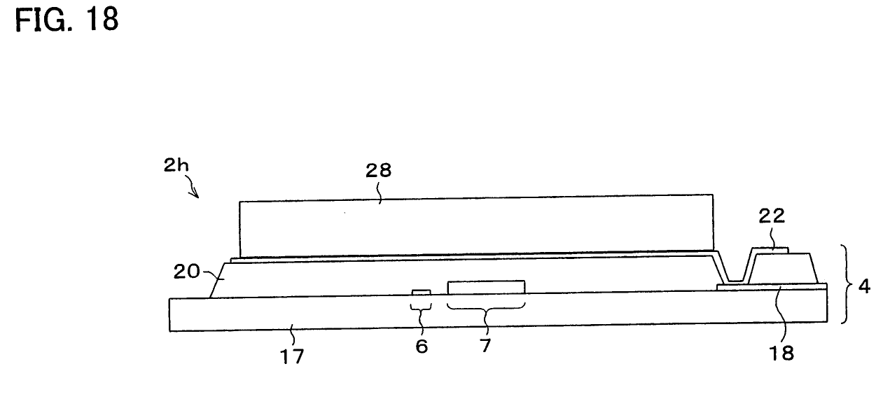

In more detail, as shown in FIG. 17, the TFT section 6a includes the gate electrode 14 on the substrate 17, the gate insulating film 24, the semiconductor layer 25, the contact layer 26, the source electrode 13, and the drain electrode 15, and the insulating protective film (first insulating layer, inorganic insulating film) 19 is provided thereon. These structures are the same as in the TFT section 6 of the aforementioned embodiment, so that description thereof is omitted. Further, the manufacturing steps thereof are the same as in the TFT section 6 of the aforementioned embodiment, so that description thereof is omitted.

As shown in FIG. 17, the TFT section 6a has a light shielding film 29 for shielding light. As in the TFT section 6a where a switching element in the TFT section 6 is separately provided from the photodetecting element, it is preferable to provide the light shielding film so as to cover at least a channel portion of the TFT section 6a.

Further, the photodiode 27 includes a semiconductor layer (diode structure) 27b provided between the bias electrode 27a and the drain electrode 15 as shown in FIG. 17. The photodiode 27 is a PIN type diode.

The photodiode 27 is formed as follows. First, as in the aforementioned embodiment, the TFT section 6a is formed on the substrate 17. Thereafter, an n-type amorphous Si film (thickness is approximately 0.05 μm), an i-type amorphous Si (thickness is approximately 0.5 μm), and a p-type amorphous Si (thickness is approximately 0.05 μm) are sequentially stacked on and above the drain electrode 15 to form the semiconductor layer 27b, and are patterned into a predetermined shape. Thus, a portion of the semiconductor layer 27b becomes a PIN type diode. Then, a transparent electrode (thickness is approximately 0.1 μm) made of ITO and the like is formed thereon as the bias electrode 27a.

Further, as in the aforementioned embodiment, the insulating protective film 19 is formed so as to entirely cover the TFT section 6a and the photodiode 27. Further, the light shielding film 29 made of black resin and the like is formed above an upper portion of the TFT section 6a. The arrangement of the light shielding film 29 is not limited to the aforementioned structure. As long as the light shielding film 29 covers at least the channel portion of the TFT section 6a, the light shielding film 29 may be formed on the organic insulating film 20 as the first insulating layer described later.

With respect to the structure provided on the substrate 17, as in the aforementioned embodiment, the organic insulating film 20 which functions as the first insulating layer is further formed, and the conductive layer 22 is formed thereon. Materials for the first insulating layer (insulating protective film 19, organic insulating film 20) and the conductive layer 22 may be the same as in Embodiment 1. The conductive layer 22 is connected to the connection electrode 18 via the opening portion (or an end face) provided in the first insulating layer. The exposing portion provided on the end face of the first insulating layer may be used as the opening portion. Thus, it is possible to obtain the same effect as in Embodiment 1. Thus, it is possible to obtain the image sensor 2g having the photodiode 27 which functions as the photodetecting element and the TFT section 6a which functions as the switching element.

Note that, the photodiode 27 is not limited to the aforementioned PIN type diode using the PIN junction of the semiconductor film. It is also possible to use a Schottky type diode using a Schottky junction or an MIS type diode using an MIS (Metal-Insulator-Semiconductor) for example.

Next, a scanning operation in the case of using the photodiode 27 as the photodetecting element is briefly described.

As described above, each pixel has the photodiode 27 which functions as the photodetecting element and the TFT section 6a which functions as the switching element.

Here, when the photodiode 27 receives light, electric charge (electric charge excited by the light) is generated in the photodiode 27. Further, the photodiode 27 is a capacitive element, so that the electric charge is stored in the photodiode 27 itself when the TFT section 6a is off. That is, in the case of using the photodiode 27 as in the present embodiment, it is not necessary to provide the pixel capacitor section 7 used to store the electric charge besides the photodiode 27. Further, when the TFT section 6a is turned on, it is possible to discharge the electric charge stored in the photodiode 27 to the outside.

Thus, when an X ray which functions as image information is irradiated for example, the image sensor 2g as shown in FIG. 14 causes the conversion layer 28 to convert the X ray into light (visible light) and stores the electric charge in the photodiode 27 of each pixel according to the light intensity. Further, under this condition, the scanning is sequentially performed so as to turn on the TFT section 6a of each pixel, thereby scanning two-dimensional electric charge information, i.e., optical image information.

As described above, the image sensor 2g may be provided with the TFT section 6a as the switching element and the photodiode 27 as the photoelectric conversion element. The image sensor 2g is arranged so that the conductive layer 22 is directly connected to the connection electrode 18, thereby reducing the cost.

Further, since the image sensor 2g which functions as the photoelectric conversion device has the conversion layer 28 as described above, it is possible to use the image sensor 2g as a radiant ray detector or an image scanning apparatus (radiant ray imaging apparatus) based on the radiant ray. Particularly in a medical radiant ray detector for detecting a weak radiant ray such as X ray, a shielding mechanism based on the aforementioned conductive layer 22 is useful. That is, it is preferable to make such an arrangement that the conductive layer 22 shields external noises. Thus, it is possible to improve S/N of a detection signal. Further, when the photodiode 27 which functions as the photoelectric conversion element is used, it is possible to detect a weak detection signal based on the weak radiant ray such as an X ray without fail since this arrangement is superior in S/N.

### Embodiment 4

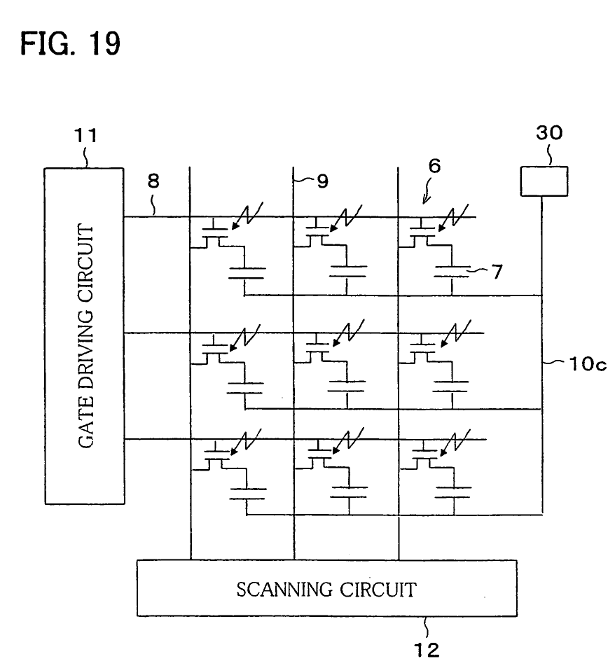

The following description will discuss further another embodiment of the present invention referring to FIG. 18 and FIG. 19. Note that, the same reference signs are given to members having the same functions as the members of the aforementioned embodiments, and description thereof is omitted. Further, various kinds of characteristics described in Embodiments 1, 2, and 3 can be applied, in combination, to the present embodiment.

An image sensor (photoelectric conversion device) 2h of the present embodiment is a device such that the photoelectric conversion device according to the present invention is applied to an X ray detector. Particularly, the image sensor 2h is arranged by combining a TFT array 4 arranged in the same manner as in Embodiment 1 with a conversion layer 28 arranged in the same manner as in Embodiment 3.

That is, as shown in FIG. 18 or FIG. 19, the conversion layer 28 may be combined with the arrangement in which: each pixel has the TFT section 6 and the pixel capacitor section 7, and the insulating protective film 19 is further formed, and the conductive layer 22 is connected thereto with the opening portion 21 provided. Further, it may be so arranged that a capacitor wiring 10c is connected to the driving circuit 30. Even in this arrangement, it is possible to realize the X ray detector by causing the conversion layer 28 to convert an X ray into light (visible light). Since a scanning operation in this case is the same as in Embodiment 1, description thereof is omitted.

If the TFT array 4 which is similar to that used in Embodiment 1 is used as a TFT array in the image sensor 2h, TFT section 6 which functions as a switching element and phototransistor is adopted in the TFT array 4. But an arrangement of a TFT array is not limited to this. A TFT array may have an arrangement that uses two transistors, namely a transistor as a switching element and a phototransistor as a photodetecting element.

In a case where a single TFT section 6 functions as both the photodetecting TFT and the switching TFT, the light shielding film 29 in FIG. 17 of Embodiment 3 is unnecessary. This is because the light shielding film stops incident light to the TFT section 6, so that it is impossible to detect the light upon photodetecting. In this case, a preferable driving method for light and TFT array is, for example, that incident light to the TFT section 6 is stopped during the period in which the TFT section 6 acts as a switching element. For example, ON/OFF of the light source is controlled such that the light is stopped during the interval for the scanning operation to the scanning line.

On the other hand, in a case of using two transistors: the TFT section 6 as a switching element and a phototransistor as a photodetecting element, the light shielding film 29 may be preferably provided with the TFT section 6a which is used as a switching TFT. Due to aforementioned arrangement, wrong operation of the TFT section 6a by incident light is prevented.

Also, as in Embodiment 3 where the photodiode 27 is used as a photodetecting element, the pixel capacitor is not required, because the photodiode 27 itself functions as the pixel capacitor. However, as in the present embodiment where the phototransistor is used as a photodetecting element, the pixel capacitor for storing the electric charge is required as described above.

As described above, the image sensor 2h is arranged so that the conductive layer 22 is directly connected to the connection electrode 18, thereby reducing the cost.

Further, since the image sensor 2h which functions as the photoelectric conversion device has the conversion layer 28 as described above, it is possible to use the image sensor 2h as a radiant ray detector or an image scanning apparatus based on a radiant ray.

As described, the photoelectric conversion device may be expressed as follows. The photoelectric conversion device includes: a first insulating layer, formed so as to cover a photoelectric conversion element and a connection electrode that are formed on a substrate, where the first insulating layer has an opening portion extending to the connection electrode; and a conductive layer formed on the first insulating layer, wherein the conductive layer is formed so as to be connected via the opening portion to the connection electrode.

Further, the photoelectric conversion device may be expressed as follows. The photoelectric conversion device includes: a first insulating layer formed so as to cover a photoelectric conversion element formed on a substrate; and a conductive layer formed on the first insulating layer, wherein the conductive layer is formed so as to be connected to a connection electrode, formed on the substrate, via an exposing portion provided on an end face of the first insulating layer in order to expose at least a part of the connection electrode.

According to the structure, it is possible to connect the conductive layer to the connection electrode by omitting a conventional conductive connector, thereby reducing the cost.

Further, the photoelectric conversion device may be expressed as follows. The photoelectric conversion device includes: a first insulating layer formed so as to cover a photoelectric conversion element formed on a substrate and a pixel capacitor section connected to the photoelectric conversion element; and a conductive layer formed on the first insulating layer, wherein a thickness of the first insulating layer is thinner in an area positioned on or above the pixel capacitor section than in other area.

According to the structure, it is possible to form a new pixel capacitor, having a capacitance according to the thickness of the first insulating layer, between the pixel capacitor section and the conductive layer, thereby securing the sufficient pixel capacitance upon highly densifying the pixel.

Further, in the foregoing structure, the photoelectric conversion device may be arranged so that the first insulating layer includes an insulating protective film, formed so as to cover the photoelectric conversion element, which protects the photoelectric conversion element, and the first insulating layer has a relative dielectric constant which is higher in the insulating protective film than in a portion other than the insulating protective film.

According to the arrangement, there is formed the insulating protective film whose relative dielectric constant is high so as to cover the photoelectric conversion element, so that it is possible to increase the pixel capacitance of the new pixel capacitor by the insulating protective film, whose relative dielectric constant is high, intervened between the pixel capacitor section and the conductive layer.

While, in an area other than the aforementioned contact area, a portion whose relative dielectric constant is low in the first insulating layer, except for the insulating protective film, may lead to decrease in the capacitance compared with a case where whole the first insulating layer is the insulating protective film.

Thus, it is possible to increase only the pixel capacitance of the pixel capacitor, required in scanning images, which stores electric charge generated by the photoelectric conversion element, without increasing the parasitic capacitance of other area such as a wiring area of a bus line for example.

Further, in the foregoing structure, the photoelectric conversion device may be arranged so that the first insulating layer includes: an inorganic insulating film formed so as to cover the photoelectric conversion element; and an organic insulating film formed on the inorganic insulating film.

In the arrangement, the inorganic insulating film protects the photoelectric conversion element from a impurity ion or moisture. Further, the organic insulating film flattens a concavo-convex (undulating) surface caused by the photoelectric conversion element.

Thus, the first insulating layer has a two-layer structure constituted of the inorganic insulating film and the organic insulating film, so that it is possible to form the insulating layer whish is superior in barrier and in flatness.

Note that, the foregoing structure may be arranged so that the insulating protective film is constituted of the inorganic insulating film and the first insulating layer other than the insulating protective film is constituted of the organic insulating film.

Further, the foregoing structure may be arranged so that the photoelectric conversion device further includes a second insulating layer formed on or above the conductive layer, which is formed on the first insulating layer.

According to the arrangement, the second insulating layer is provided on or above the conductive layer, so that a scanned document is not in contact with the conductive layer, thereby preventing the document from deteriorating the conductive layer. Thus, since the conductive layer is not deteriorated, it is possible to improve the reliability in the antistatic treatment.

Further, when the second insulating layer is made of material having high abrasion resistance, it is possible to prevent deterioration of resolution that is caused by flaws and dusts brought about by a document etc. which is in contact with the conductive layer.

Further, the foregoing structure may be arranged so that the photoelectric conversion device includes a conversion layer, which is formed on or above the conductive layer formed on the first insulating layer, which converts a radiant ray into light.

The conversion layer may be provided directly on the conductive layer, or may be provided on the second insulating layer formed on the conductive layer for example.

Here, the radiant ray is an X ray for example, but is not limited to this. The radiant ray may be an ultraviolet ray. In more detail, the conversion layer converts an X ray, which is an electromagnetic wave whose wave length ranges approximately from 0.01 to dozens nm, or an ultraviolet ray, which is an electromagnetic wave whose wave length ranges approximately from dozens to 360 nm, into visible light (wave length ranges approximately from 360 to 830 nm).

According to the structure, a radiant ray, such as an X ray, which is incident on the photoelectric conversion device is converted into light by the conversion layer, so that it is possible to detect the radiant ray by detecting the light. Thus, it is possible to make the photoelectric conversion device function as a radiant ray detector or a radiant ray imaging device. Also this structure can realize the features of the present invention.

Further, the image scanning apparatus may be expressed as follows. The image scanning apparatus includes any one of the aforementioned photoelectric conversion devices, wherein the photoelectric conversion device is used as an image scanning sensor.

Thus, since the photoelectric conversion device which can be manufactured at lower cost is used as the image scanning sensor, it is possible to provide the image scanning apparatus which can be manufactured at lower cost.

Further, when the photoelectric conversion device is arranged so as to include the conductive layer connected to the aforementioned connection electrode, the static electricity does not cause a scanning error, so that it is possible to scan images without fail.

Further, when the photoelectric conversion device is arranged so as to include a new pixel capacitor between the pixel capacitor section and the conductive layer as described above, the pixel capacitance is increased, thereby improving the scanning quality.

Further, the manufacturing method of the photoelectric conversion device may be expressed as follows. The manufacturing method of the photoelectric conversion device includes the steps of: forming a photoelectric conversion element and a connection electrode on a substrate; providing a first insulating layer for covering the photoelectric conversion element and the connection electrode, and forming an opening portion, extending to the connection electrode, in the first insulating layer; and forming a conductive layer, connected via the opening portion to the connection electrode, on the first insulating layer.

Further, the manufacturing method may be expressed as follows. The manufacturing method of the photoelectric conversion device includes the steps of: forming a photoelectric conversion element and a connection electrode on a substrate; providing a first insulating layer for covering the photoelectric conversion element and the connection electrode, and forming an exposing portion on an end face of the first insulating layer so that at least a part of the connection electrode is exposed; and forming a conductive layer, connected via the exposing portion to the connection electrode, on the first insulating layer.

By using the manufacturing method of the photoelectric conversion device, it is possible to manufacture the aforementioned photoelectric conversion device. Thus, it is possible to omit the conductive connector, thereby reducing the manufacturing cost. Further, it is possible to omit the process for making connection using the conductive connector, thereby further reducing the cost.

Further, the manufacturing method may be expressed as follows. The manufacturing method of the photoelectric conversion device includes the steps of: forming a photoelectric conversion element and a pixel capacitor section, connected to the photoelectric conversion element, on a substrate; forming a first insulating layer so as to cover the photoelectric conversion element and the pixel capacitor section; and forming a conductive layer on the first insulating layer; wherein the first insulating layer is formed so that a thickness of the first insulating layer is thinner in an area positioned on or above the pixel capacitor section than in other area.

By using the manufacturing method of the photoelectric conversion device, it is possible to manufacture the aforementioned photoelectric conversion device. Thus, it is possible to increase the pixel capacitance of the first insulating layer, which functions as the pixel capacitor, between the pixel capacitor section and the conductive layer without largely changing conventional processes. Thus, it is possible to obtain the sufficient pixel capacitance upon densifying the pixel.

Further, the foregoing arrangement may be arranged so that the method further includes the step of forming a second insulating layer on or above the conductive layer formed on the first insulating layer.

By using the manufacturing method of the photoelectric conversion device, it is possible to manufacture the aforementioned photoelectric conversion device. Thus, the second insulating layer is provided on the conductive layer as described above, so that a scanned document is not in contact with the conductive layer, thereby preventing the document from deteriorating the conductive layer.

Further, the arrangement may be arranged so that the method further includes the step of forming a conversion layer, which converts a radiant ray into light, on or above the conductive layer formed on the first insulating layer.

By using the manufacturing method of the photoelectric conversion device, it is possible to manufacture the aforementioned photoelectric conversion device. Thus, it is possible to make the photoelectric conversion device function as a radiant ray detector or a radiant ray imaging device.

As described above, the photoelectric conversion device (image sensor) and the image scanning apparatus of the present invention make it easier to manufacture them by omitting the conductive connector, and make it possible to increase the pixel capacitance. That is, since the conductive layer and the connection electrode of the image sensor are directly in contact with each other so as to be electrically connected to each other, the conventional conductive connector is not required. As a result, it is possible to reduce the cost by omitting the conductive connector, and it is possible to further reduce the cost by reducing the processes. Further, since the conductive connector is not required, accuracy is not required upon manufacturing, so that it is possible to provide an image sensor which can be easily manufactured at lower cost. Further, the opening portion is provided, and a new pixel capacitor is formed between the conductive layer and the polar plate of the pixel capacitor section, so that it is possible to increase the pixel capacitance without largely changing conventional processes. Thus, it is possible to; provide an image sensor which assures the sufficient pixel capacitance upon highly densifying the pixel of the image sensor and can easily manufactured at lower cost.

The invention being thus described, it will be obvious that the same may be varied in many ways. Such variations are not to be regarded as a departure from the spirit and scope of the invention, and all such modifications as would be obvious to one skilled in the art intended to be included within the scope of the following claims.

Further, it is possible to combine features recited in the following claims and technical means recited in BEST MODE FOR CARRYING OUT THE INVENTION with each other as required, and features obtained by the combinations are included in the technical scope of the present invention.

That is, it is needless to say that: for example, an arrangement in which features shown in FIG. 7 and FIG. 8 and features shown in FIG. 9 and FIG. 11 are combined is included in the technical scope of the present invention.

Note that, a photoelectric conversion device and an image scanning apparatus in related technologies are briefly described as follows. Japanese Unexamined Utility Model Publication No. 8055/1990 (Jitsukaihei 2-8055) and Japanese Unexamined Patent Publication No. 243547/1993 (Tokukaihei 5-243547) recite a thin film photosensor, but do not disclose the structure in which the conductive layer is provided on the image sensor. Further, Japanese Unexamined Patent Publication No. 711173/1989 (Tokukaihei 1-711173) (U.S. Pat. No. 4,982,079; No. 5,086,218; No. 5,160,835) and Japanese Unexamined Patent Publication No. 245853/1992 (Tokukaihei 4-245853) recite an image scanning apparatus having a conductive layer (shield layer) on an image sensor, but do not disclose the arrangement for making it easier to connect the conductive layer to the connection electrode of the TFT array.

### INDUSTRIAL APPLICABILITY

The photoelectric conversion device and the image scanning apparatus of the present invention can be manufactured by simple processes, so that they can be applied as a photoelectric conversion device and an image scanning apparatus which are manufactured at lower cost. Further, the photoelectric conversion device and the image scanning apparatus of the present invention can be applied to manufacturing a photoelectric conversion device and an image scanning apparatus whose pixels are highly densified by increasing the pixel capacitor without largely changing conventional processes. Further, the image scanning apparatus of the present invention has the conversion layer for changing a radiant ray into light, thereby functioning as a radiant ray detecting apparatus.

1. A photoelectric conversion device, comprising: a first insulating layer, formed so as to cover a photoelectric conversion element and a connection electrode that are formed on a substrate, where the first insulating layer has an opening portion extending to the connection electrode; and a conductive layer formed on the first insulating layer, wherein the conductive layer is formed so as to be connected via the opening portion to the connection electrode.

2. A photoelectric conversion device, comprising: a first insulating layer formed so as to cover a photoelectric conversion element formed on a substrate; and a conductive layer formed on the first insulating layer, wherein the conductive layer is formed so as to be connected to a connection electrode, formed on the substrate, via an exposing portion provided on an end face of the first insulating layer in order to expose at least a part of the connection electrode.

3. A photoelectric conversion device, comprising: a first insulating layer formed so as to cover a photoelectric conversion element formed on a substrate and a pixel capacitor section connected to the photoelectric conversion element; and a conductive layer formed on the first insulating layer, wherein a thickness of the first insulating layer is thinner in an area positioned on or above the pixel capacitor section than in other area.

4. The photoelectric conversion device as set forth in claim 3, wherein:
the first insulating layer includes an insulating protective film, formed so as to cover the photoelectric conversion element, which protects the photoelectric conversion element, and the first insulating layer has a relative dielectric constant which is higher in the insulating protective film than in a portion other than the insulating protective film.

5. The photoelectric conversion device as set forth in claim 1, wherein the first insulating layer includes: an inorganic insulating film formed so as to cover the photoelectric conversion element; and an organic insulating film formed on the inorganic insulating film.

6. The photoelectric conversion device as set forth in claim 1, further comprising a second insulating layer formed on or above the conductive layer, which is formed on the first insulating layer.

7. The photoelectric conversion device as set forth in claim 1, further comprising a conversion layer, which is formed on or above the conductive layer formed on the first insulating layer, which converts a radiant ray into light.

8. An image scanning apparatus, comprising the photoelectric conversion device as set forth in claim 1, wherein the photoelectric conversion device is used as an image scanning sensor.

9. A manufacturing method of a photoelectric conversion device, comprising the steps of: forming a photoelectric conversion element and a connection electrode on a substrate; providing a first insulating layer for covering the photoelectric conversion element and the connection electrode, and forming an opening portion, extending to the connection electrode, in the first insulating layer; and forming a conductive layer, connected via the opening portion to the connection electrode, on the first insulating layer.

10. A manufacturing method of a photoelectric conversion device, comprising the steps of: forming a photoelectric conversion element and a connection electrode on a substrate; providing a first insulating layer for covering the photoelectric conversion element and the connection electrode, and forming an exposing portion on an end face of the first insulating layer so that at least a part of the connection electrode is exposed; and forming a conductive layer, connected via the exposing portion to the connection electrode, on the first insulating layer.

11. A manufacturing method of a photoelectric conversion device, comprising the steps of: forming a photoelectric conversion element and a pixel capacitor section, connected to the photoelectric conversion element, on a substrate;
forming a first insulating layer so as to cover the photoelectric conversion element and the pixel capacitor section; and forming a conductive layer on the first insulating layer;
wherein the first insulating layer is formed so that a thickness of the first insulating layer is thinner in an area positioned on or above the pixel capacitor section than in other area.

12. The method as set forth in claim 9, further comprising the step of forming a second insulating layer on or above the conductive layer formed on the first insulating layer.

13. The method as set forth in claim 9, further comprising the step of forming a conversion layer, which converts a radiant ray into light, on or above the conductive layer formed on the first insulating layer.
